(19) United States
(12) Patent Application Publication
(10) Pub. No.: US 2007/0267626 A1
(43) Pub. Date: Nov. 22, 2007

(54) Semiconductor structure

(76) Inventors: Michael Indlekofer, Aachen (DE); Hans Luth, Aachen (DE); Arnold Forster, Simmerath (DE)

Correspondence Address: K.F. ROSS P.C., 5683 RIVERDALE AVENUE, SUITE 203 BOX 900, BRONX, NY, 10471-0900, US

(21) Appl. No.: 10/588,243

(22) PCT Filed: Jan. 21, 2005
(86) PCT No.: PCT/DE05/00080

§ 371 Date: Mar. 14, 2007

(30) Foreign Application Priority Data
Feb. 3, 2004 (DE) 10 2004 005 363.4

(51) Int. Cl. H01L 29/06

(52) U.S. Cl. 257/24; 257/E29.024

(57) ABSTRACT

The invention concerns a semiconductor structure comprising at least one first material region and a second material region, whereby the second material region epitaxially surrounds the first material region and forms a boundary surface. The structure is characterized in that Fermi level pinning is present on the non-epitaxial boundary surface of the second material region located opposite the boundary surface of both material regions, and the first material region forms a quantum well for free charge carriers. This advantageously results in enabling a controllable charge carrier concentration to be set in the quantum well

The invention regards a semiconductor structure.

In semiconductor electronics it is desired to develop components with shorter and shorter switching times and less power requirements. This object is achieved by micro structures made of semiconductor materials with as short paths as possible between the injection and extraction points (channel lengths), which have to be traversed by the electrons, and high mobilities, which means with a good response to external electrical fields.

In the laboratory, standard values for so-called high electron mobility transistors (HEMT) with channel lengths of <1 μm with mobilities of μₑ>10⁶ cm²/Vs and switching times of <10 ps are achieved. In a HEMT, several well defined layers of different semiconductor materials are produced, e.g. of GaAs and AlGaAs, with thicknesses in the range of nanometers, which means down to some atomic layers, and which are specifically doped with different electrically active impurity atoms. These layers are structured laterally on the plane in fractions of μm.

In the HEMT, the principle of modulation doping is used for two-dimensional semiconductor heterostructures. In this field, a spatial separation of doped semiconductor material and undoped semiconductor material of the transistor channel, in the interface of which a controllable, two-dimensional charge carrier gas, e.g. in form of a conduction band electron gas is formed, is achieved by a unilateral, planar, epitaxially grown semiconductor heterostructure. Due to the separation of channel and doping impurities, a highly improved mobility of the charge carrier gas is ensured.

In the HEMT, there is a high concentration of charge carriers which have a high mobility parallel to the interface while remaining confined to a range of e.g. 10 nanometers in a layer with a small band gap at the interface to a second layer with a high band gap.

A quantum well is a structure acting as potential well for the crystal electrons in one spatial direction with an extension similar to the de Broglie wavelength. This condition is fulfilled in most semiconductors with dimensions of some 10 nanometers or less. A so-called quasi two-dimensional electron gas is formed. The charge carriers can still freely move in x and y direction; along the z-axis, the energy eigenvalues are quantified.

The high demands regarding the perfection of such layers and sections in the nanostructures can be fulfilled by heteroepitaxy, e.g. in a molecular beam epitaxy system. The structures for the formation of a two-dimensional electron gas are produced by means of such procedures.

If the dimensions of the conductor paths are similar to the dimensions of the Fermi waves, the possible electron paths are confined. In that case, quantum mechanics gain significant influence on the stationary conditions and on the transport of the electrons due to the wave character of the electrons.

If the dimension of a two-dimensional electron gas is further confined by lateral structuring, one-dimensional or even zero-dimensional (which means systems confined in each spatial direction) so-called quantum dots are realized.

Methods for the production of structures are known from the state of the art, in which the free electrons or holes are confined within the range of nanometers in certain spatial directions.

Such components, based on one-dimensional or zero-dimensional semiconductor structures are very promising systems for improved transistor and diode components and novel quantum nanocomponents due to quantum mechanical effects. The dimension reduction in two, or respectively three, spatial directions on one-dimensional or respectively zero-dimensional structures with reference to the mobility of the charge carriers is based on the quantization of the confined degrees of freedom of the free charge carriers. Thus, the de Broglie wavelength of the charge carriers, that is of the crystal electron or of the crystal hole, has to correspond to the dimensions of the confined spatal directions.

From Björk et al (Björk, M. T., Ohlsson, B. J., Sass, T., Persson, A. I., Thelander, C., Magnusson, M. H., Deppert, K., Wallenberg, L. R., Samuelson, L. (2002), One-dimensional heterostructures in semiconductor nanowhiskers, Applied Physics Letters 80, 1058) epitaxially and partially self-organized growth of one-dimensional semiconductor structures, so-called whiskers, is known.

It is known from Panev et al (Panev, N., Persson, A. I., Sköld, N., L. Samuelson (2003), Sharp exciton emission from single InAs Quantum dots in GaAs nanowires. Applied Physics Letters 83, 2238) to transport charge carriers from a GaAs substrate to an InAs isle by means of a nanowire made of GaAs and to generate luminescence.

Disadvantageously, these structures have a barely controllable charge carrier concentration in the quantum dot.

It is the object of the invention to provide a simply constructed semiconductor structure by means of which a high concentration of free charge carriers can be set and the spatial course of which can be directly controlled in a zero-dimensional or one-dimensional quantum well.

The object is attained by a semiconductor structure according to the main claim. Advantageous embodiments result from the depending claims.

According to the invention, the semiconductor structure has at least one first material region and a second material region. The second material region surrounds the first material region and is epitaxially provided on the first material region. In the semiconductor structure, Fermi Level Pinning is observed at the epitaxial exterior surface of the second material region situated opposite to the interface of both material region and the first material region forms a quantum well for free charge carriers.

Preferably the quantum well is not disturbed by Fermi Level Pinning.

The first material region forms a quantum well for free charge carriers, so that these are quantum mechanically, zero-dimensionally or one-dimensionally confined in their mobility, or respectively the conditions for charge carriers are zero-dimensional or one-dimensional.

Thus, the advantageous result is achieved that in the quantum well of the first material region, provided on the inside, the concentration and mobility of the charge carriers is high, without this material region having to be highly doped. In contrast to the state of the art, one-dimensional charge carrier transport in the first material region or respectively quantum well can advantageously be adjusted, a fact that may be used for the production of transistors with high charge carrier mobility.

In addition to the one-dimensional quantum structures, such as whiskers and lithographically produced mesa structures, islands with no Fermi Level Pinning can be advantageously produced at the interface of the quantum well. The whiskers can be formed as depleted structures with further heterostructures, e.g. with GaAs/AlGaAs or GaN/AlGaN sections.

Thus, it is advantageously ensured that the positive characteristics of these semiconductor structures are also used in more complex structures, up to lasers and transistors.

The energetic minimum of the quantum well of the first material region is either below the Fermi energy in the balance or has a distance to the Fermi energy which is inferior or equal to k_{B}T. It is then advantageously ensured that a sufficient amount of charge carriers is present in the quantum well and can be used for transistors, diodes and so on.

The dimensions or the diameter of the first material region is so small that the mobility of the charge carriers is quantum mechanically confined in at least two spatial directions.

The first material region is provided on the second material region, or surrounded by the latter such that the undesired Fermi-Level-Pinning is shifted from the interface of both material regions to the interface of the second material region situated opposite to that interface. The Fermi Level Pinning is observed at the nonepitaxial exterior surface of the second material region adjacent to potential further material regions. If further epitaxial interfaces are provided at the second material region, Fermi Level Pinning is observed at the first non-epitaxial exterior surface.

In the semiconductor structure, the shortest distance between the quantum well from the center to the non-epitaxial exterior surface, where the Fermi-Level-Pinning takes place, should not fall below the depletion length d. A definition of the depletion length can be taken from Lüth (Lüth H (1996). Surfaces and interfaces of solid materials. 3. Edition, Springer Study Edition, Page 458). The depletion length is a material characteristic which depends on the doping.

Thus, the concentration of free charge carriers and their spatial movements in such one-dimensional and zero-dimensional semiconductor structures can be advantageously set and controlled by means of a lateral epitaxial surrounding, if necessary with doping and/or polarization charges of the interfaces. Charge carriers can penetrate into the first material region from dopant atoms of the second material region. One or several optional exterior gates can control the charge carrier concentration in the first material region without the undesired Fermi Level Pinning at the interface from the first to the second interface influencing them.

At the non-epitaxial interfaces or exterior surface of the semiconductor structure Fermi Level Pinning is observed because of the interface conditions. According to the energetic position of the Fermi Level Pinning of the structure, two results are possible: the depletion or the enhancement of free charge carrier in the semiconductor in proximity of the interface. Within the framework of the invention, this condition is used for the charge carrier concentration in the quantum well. The Fermi-Level-Pinning present at the interface between two material regions is shifted thanks to an adequate choice of the materials or of the dimensions and/or, where required, of the doping of the two material regions adjacent to the first, nonepitaxially formed interface of an exterior material region and therefore it has no or at least less influence on the charge carrier concentration and on the mobility in the quantum well of the first material region. This fact is used for the control of the charge carrier concentration in the quantum well by means of electrodes.

For the class of the semiconductors with depleted interfaces made of GaAs, InP or GaN materials for the first material region, the concentration of free charge carriers in components made thereof, particularly with diameters in the dimensions of the depletion length and inferior to them is humble and practically cannot be influenced by external factors, such as e.g. electrodes. It is not possible to resort to very high dopings due to the negative influence on the mobility of the charge carriers and on the control. Such a depleted structure cannot be used for electronic components.

Furthermore, it was discovered that, in the first material region, for the class of the semiconductors with enhanced interfaces made of e.g. InAs, InSb and other so-called narrow-gap materials, the concentration of free charge carriers in the proximity of the interface between the first and the second material region is practically invariable and is a material characteristic. The free charge carriers provide metal-like characteristics, particularly characteristics regarding the electronic transport and the optical response. Practically, they cannot be influenced by doping and/or external factors, such as, for example, electrodes. In components consisting of materials with enhanced interfaces, particularly of dimensions in the size of the enhancement length, the electronic characteristics are practically dominated by the free charge carriers in the proximity of the interface and are therefore invariable. Moreover, such a structure cannot be used for electronic transistor components disposed with a grid.

The materials which might be doped and/or the thickness of the two material regions in the semiconductor structure are selected, according to the invention, for the formation of a first material region which is directly provided with charge carriers such that the Fermi Level Pinning is shifted from the interface to the non-epitaxial interface of the second material region situated opposite to the first interface. If necessary, at least one epitaxially or non-epitaxially provided material region is provided on the second material region.

In the case of this further material region being epitaxially provided on the second material region, the further material region advantageously forms a continuous ending to the semiconductor structure before further layers, for example with gate function are provided.

The material of the further material region can be identical to the material of the first material region for reasons of passivation of the semiconductor structure.

The semiconductor structure can also comprise a metal used as material for the further material region.

In a further embodiment of the invention, the first material region has a dimension or respectively a diameter of less than 100 nanometers, particularly of 0.5 to 50 nanometers.

According to the state of the art, a semiconductor structure with a first material region of such dimensions is particularly susceptible to Fermi Level Pinning and it is the first time that it can be provided having a high charge carrier concentration.

In a particularly advantageous semiconductor structure GaAs is provided as material for the first material region and/or AlGaAs as material for the second material region. These materials can be easily epitaxially connected to each other due to the quasi lattice matching and are then provided virtually without any dislocations. Other semiconductor structures with such lattice matching material regions can be used without limiting the invention.

Due to doping, the second material region can have an optional, even inhomogeneous doping profile. However, it is also possible to use polarization charges at the interface between the first and the second material region for improving the charge carrier profile in the quantum well. The polarization charges are used dependently on the crystallographic orientation of the interface areas in relation to the axes of the whole crystal so that doping in the second material region can also be avoided.

The second material region can have several clamp-like surfaces which are provided epitaxially to each other. The second material region, starting from e.g. the interface of the first material region made of GaAs, can consist of a section of 20 nanometers thick sections made of Al_{0.3}Ga_{0.7}As, AlAs and Al_{0.51}Ga_{0.49}As. A thin, undoped or lowly doped spacer represents the outward end of the second material region. The spacer reduces the dispersion of charge carriers within the first material region. The first material region made of GaAs is encompassed by this sequence. The first material region, on the other hand, can have heterostructures in longitudinal direction, that is perpendicular to the second material region.

This way, the first and the second material regions can be optionally interrupted by separately grippable heterostructures. Thereby, for example resonant tunnel diodes can be produced.

If the first material region of the semiconductor structure has a low lateral extension of for example less than 50 nanometers, it should have a charge carrier concentration of at least 10¹⁰ cm⁻³, especially a charge carrier concentration of at least 10¹⁶ cm⁻³. One or several gates for the control of the charge carrier concentration can be provided.

In the following, the invention is to be described in detail by means of exemplary embodiments and the enclosed figures.

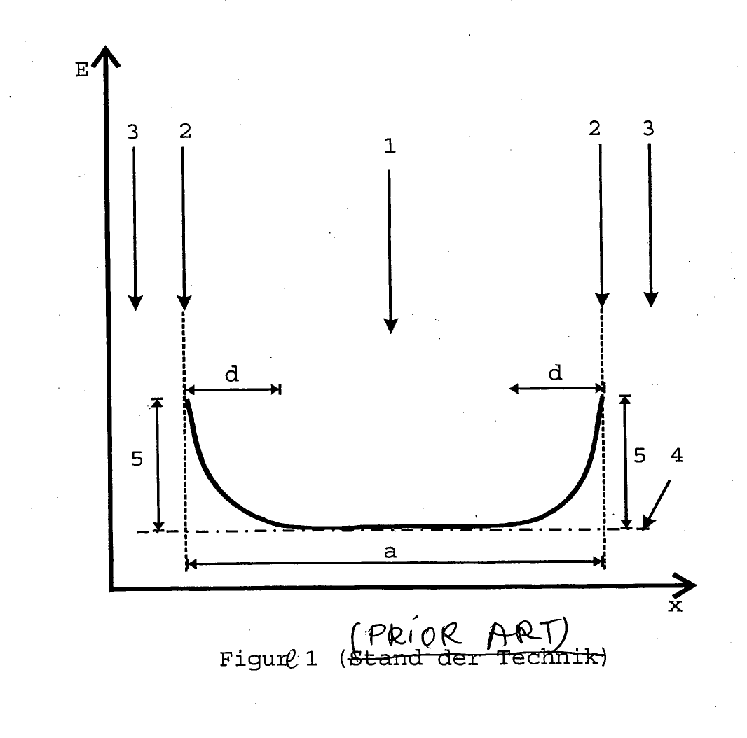

FIG. 1 shows a section of the electronic band scheme for a semiconductor structure according to the state of the art. The conduction band edge (E) for the electrons is displayed as function of the radial position x within a large and thus partially depleted structure. The same is true for the valence band edge regarding the holes. This band edge is a potential for charge carriers.

According to the state of the art, the distance a is large and indicates the dimension of a first material region 1, on which a second material region 3 (not shown), e.g. a metal, gas or plastic or other isolator or semiconductor is non-epitaxially provided. The distance d represents the depletion length starting from the Fermi Level Pinning at the interface 2 of the considered semiconductor. If the structure is partially depleted, d is < a and thus comparatively harmless for the transport of the charge carriers to the interface 2 between the two material regions. The depleted sections of the material region 1 only represent only a small portion of the whole structure due to the fact that d is < a. The Fermi Level Pinning at the non-epitaxial interface has an energetic value dimension according to arrow 5.

The Fermi energy (=Fermi Level) in the balance is indicated by the dot-dash line 4. According to arrow 5, the energetic value of the Fermi-Level-Pinning is a fixed, energetic distance to the conduction band edge in the area of the interface 2 due to interface conditions.

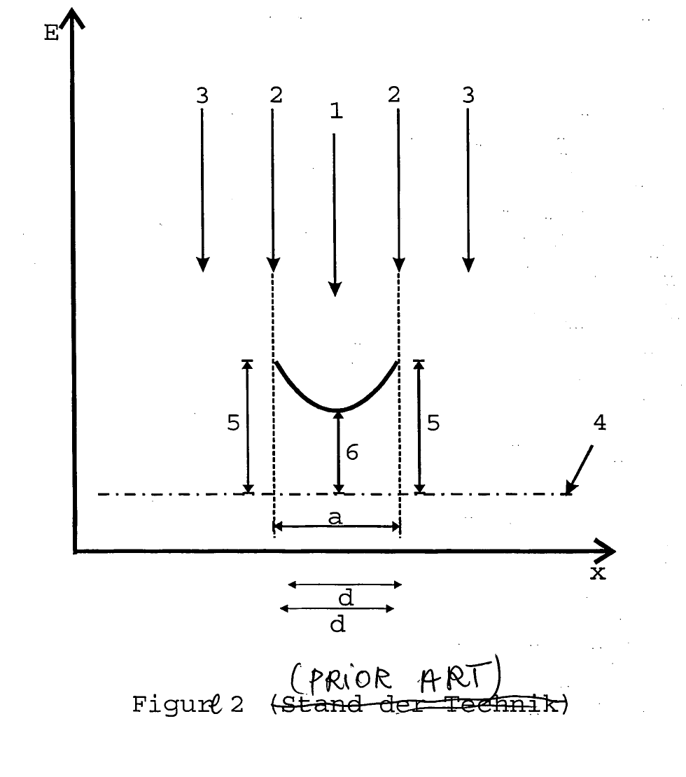

FIG. 2 shows a further conduction band edge E for electrons in a semiconductor structure as function of the radial position x. The dimension of material region 2 is very small compared to the semiconductor structure of FIG. 1 and thus the material region 1 is completely depleted. The same is true for the valence band edge for the holes. This band edge is a potential for charge carriers.

The distance a represents again the spatial dimensions of the material region 1 (e.g. 20 nanometers). The material region 3 (not shown) is non-epitaxially provided on the material region 1. The material region 3 consists e.g. of a metal or a gas, a plastic or a different isolator or semiconductor.

The distance d indicates again the depletion length. In this case the depletion length d is greater than the dimensions a of the material region 1. The potential minimum is indicated by arrow 6. Due to d>a the potential minimum energetically exceeds k_{B}T (T=temperature, k_{B}T [should read k_{B}]=Boltzmann constant) of the Fermi energy in the balance, indicated by the dot-dash line 4. Thus, the interface 2 between the material region 1 and the material region 3 is completely depleted. The interface 2 is concerned by Fermi Level Pinning (see arrow 5) due to interface conditions. The arrow 5 indicates the energetic level of the Fermi-Level-Pinning. It is obvious that a fixed, energetic distance of the conduction band edge in the area of the interface 2 is present due to interface conditions.

It is to be noted that for the class of semiconductors with depleted interfaces according to the state of the art, such as e.g. GaAs, InP and GaN, whether they are free or on a substrate, the concentration of free charge carriers in components produced thereof, particularly with dimensions smaller than 100 nanometers and in the size of the depletion length and smaller, is very small and virtually cannot be influenced by external sizes, e.g. electrodes. The depletion length is a material characteristic which depends on the doping. However, even if the material for the first layer consists of highly doped GaAs, such dimensions lead to the fact that no useful transistor/tunnel diode can be produced due to the impurity dispersions with low mobility of the charge carriers.

Simulations show that despite high doping, a structure of this type practically remains completely depleted. Fermi Level Pinning is always observed at the interface 2 at about 0.65 eV from the conduction band edge E so that the semiconductor structure from the material region 1 (30 nanometer Gabs, n-doped with 10¹⁹ cm⁻³) and the material region 3 (metal, air and so on) are completely depleted (T=300 K).

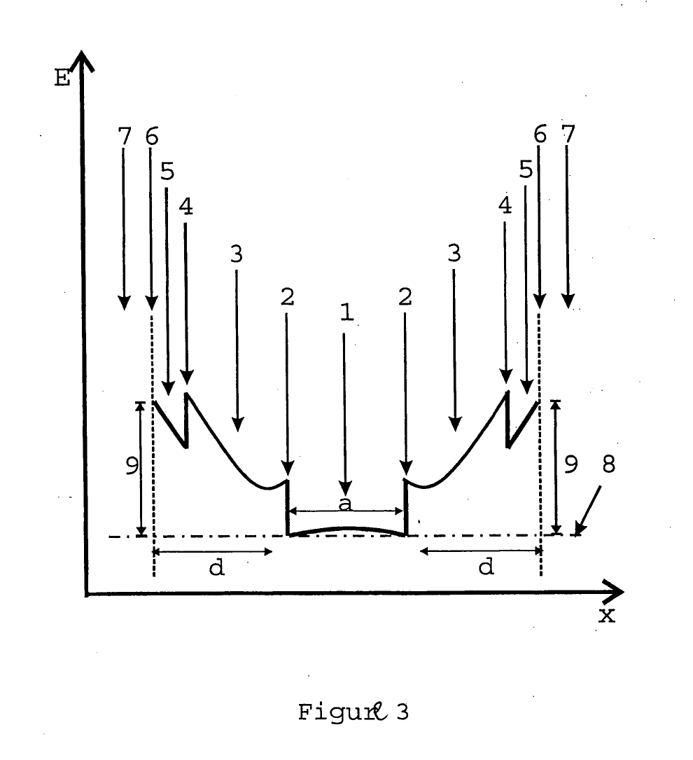

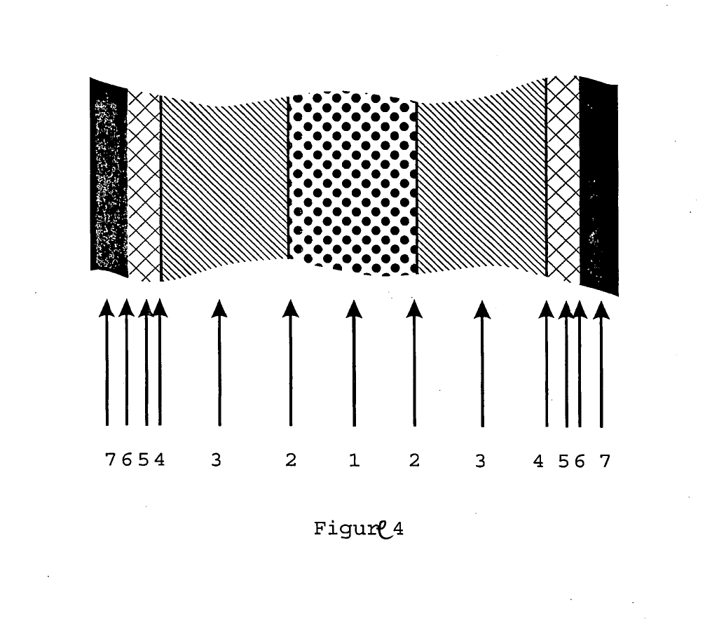

FIG. 3 shows the conduction band edge (E) as function of the radial position (x) within a semiconductor structure according to the invention. In FIG. 3 is displayed the conduction band edge E along the profile of a one-dimensional semiconductor structure. A profile of the material regions is schematically shown in FIG. 4.

The semiconductor structure comprises a first material region 1 of the dimension a which is epitaxially surrounded by a second material region 3. The material region 1 is an island or a whisker. The material region 3 is epitaxially provided on the material region 1. The same is true for the valence band edge regarding holes. This band edge is a potential for charge carriers.

The materials of both section 1, 3 are selected such that the material of the first material region 1 forms the quantum well. The quantum well is situated on the level of the Fermi energy 8 and its energetic level is indicated by the dot-dash line. At the interface 2 between the first material region 1 and the material region 3 epitaxially provided thereto, the conduction band edge E is lowered compared to the material region 3.

A potential jump is observed at the hetero interface 2 (band discontinuity). Unlike in the state of the art, however, no Fermi Level Pinning is observed at the interface 2, but instead it is observed at the first non-epitaxial interface 6 between the second material region 3 and a further material region 5, which is optionally also provided on the material region 3, sometimes surrounding it, and which acts as cap material of the semiconductor structure. The material region 5, which is optionally provided, serves for the passivation of the thus surrounded semiconductor structure. In the case that the layer 5 is not epitaxially provided on the layer 3, Fermi Level Pinning would occur at the interface 4.

The interface 6 of the semiconductor structure is concerned by Fermi Level Pinning due to interface conditions. The whole semiconductor structure is surrounded by a non-epitaxial material, e.g. an isolator 7 or a metal 7 or a non-epitaxial semiconductor 7. The isolator can be e.g. a gas like air or a plastic.

The energetic value of the Fermi Level Pinning, indicated by arrow 9 and thus the distance of the energetic distance of the conduction band edge E fixed at the interface 6 by the Fermi-Level 8 in the balance is indicated by the arrows 9.

It is to be noted that thanks to the choice of material of the layers 1 and 3, the dimensions of the layers and sometimes thanks to their dopings, the Fermi Level Pinning at the interface 6 is that distant to the interface 2, that the depletion length d extending from interface 6 does not influence the quantum well negatively, so that the charges can be directly introduced into this area. In the semiconductor structure the shortest distance of the quantum well to the non-epitaxial outer surface 6 (Fermi-Level-Pinning) should not fall below the depletion length d as far as the length is concerned.

FIG. 4 shows a section of a profile radially cut through a surrounding whisker according to FIG. 3. The inner material region 1 is completely surrounded epitaxially by the material region 3. Cap material 5 can be epitaxially provided on the material region 3 and metallic Schottky gate material 7 can be optionally provided on the cap material 5. The other reference signs are also corresponding to those used in FIG. 3.

Particularly GaAs as material of section 1 and AlGaAs as material of section 3 are used in the semiconductor structures according to the invention.

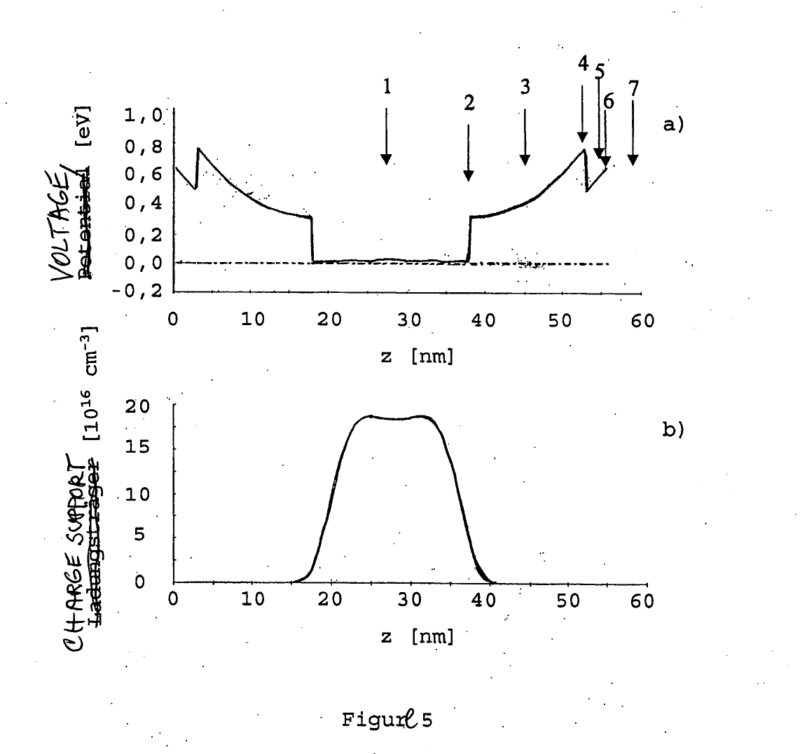

A simulation (FIG. 5) regarding the two semiconductor structures according to FIG. 3, 4 illustrates the mode of action of the lateral epitaxial surrounding and the concentration of free charge carriers inside the structure, that is within the quantum well of material region 1, which is significantly increased compared to the state of the art. The dimensions of the surrounding and the doping thereof are selected such that the free charge carriers are maximized in order to improve their mobility at the inside, separated in space by doping and interfaces. A change of the materials according to the invention and/or material thicknesses and/or dopings allows a defined variation of the concentration of the free charge carriers and/or of their spatial distribution.

FIG. 5 shows an approximate simulation of a two-dimensional layer package with self consistent Hartree potential, LDA-exchange and quantum mechanical calculation of the electron charges (free charge carriers).

The simulation related to an undoped material region 1, consisting of GaAs with a thickness of 20 nanometers, which was completely surrounded by a 15 nanometer thick material region 3 consisting of Al_{0.3}Ga_{0.7}As. The material region 3 is n-doped with 3.0×10¹⁸ cm⁻³ and completely ionized. An undoped, 5 nm thick material region 5 made of GaAs is provided on the material region 3 in order to prevent the Al from being oxidized. The material region 5 is provided at a non-epitaxial metallic outer material 7 (e.g. Schottky contact).

The Fermi energy is again indicated by means of a dot-dash line. The upper diagram displays a) the course of the conduction band edge (potential) as function of the position (z). The lower diagram displays b) the development of the concentration of the free charge carriers (charge) as function of the position (z). Fermi Level Pinning is only observed at the interface 6 at about 0.65 ev from the conduction band edge E (see FIG. 4). Only the right part shows reference signs 1 to 7.

It is to be noted that in the area of the material region 1 a direct charge carrier concentration up to a value of 2×10¹⁷ cm⁻³ achieved. This value is about 10⁹ higher than the values known so far. This enhancement of charge carriers in the material region 1 with dimensions of 20 nanometers and less can be used, depending on the application, for optical purposes (zero-dimensional surrounding of an island), transistors or resonant tunnel diodes or super lattices (one-dimensional surroundings of whisker structures) or different stack structures within a whisker with several transistors and gates and/or hetero structures within the whiskers.

Instead of the GaAs-AlGaAs semiconductor structure described above, a semiconductor structure made of the following materials can be used without limiting the scope of the invention:
Al_{y}Ga_{1-y}As (material region 1) and AlₓGa₁₋ₓAs (material region 3) with x>y for the formation of the step in the quantum well (discontinuity of the band);
InP (material region 1) and InₓAl₁₋ₓAs with a value x allowing the lattice to match to InP;
InₓGa₁₋ₓAs (material region 1) and InP (material region 3) with a value x allowing a lattice matching to InP;
Al_{y}Ga_{1-y}N (material region 1) and AlₓGa₁₋ₓN with x>y;
Si (material region 1) and SiₓGe₁₋ₓ (material regions 1 or 3), depending on the crystal torsion and on the issue whether electrons or holes are required;
ZnO (material region 1) and AlₓGa₁₋ₓN (material region 3);
InAs (material region 1) and AlSb (material region 3).
The semiconductor structures can be both depletion structures and enhancement structures.

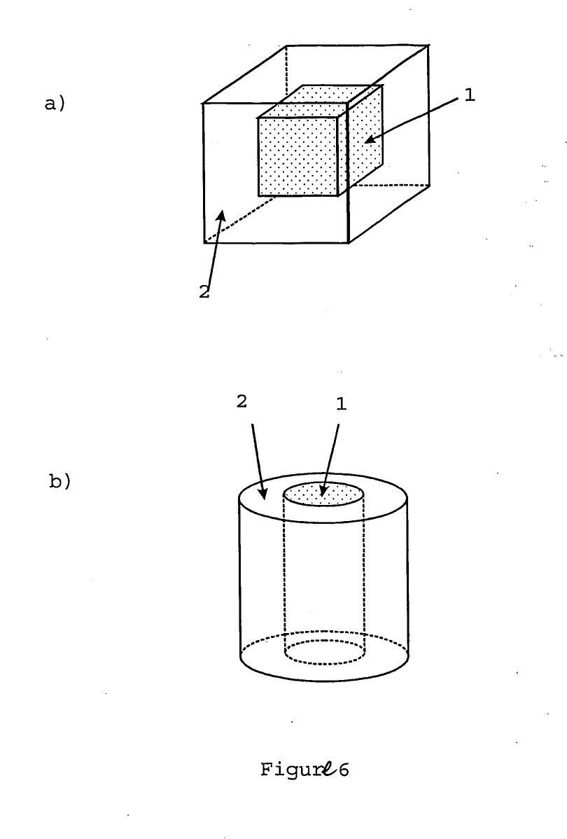

FIGS. 6a, b show the characteristic geometry of the one-dimensional and zero-dimensional structures concerned in a schematic perspective. The actual geometric shaping (e.g. round, quadratic, hexagonal) in the figures was only chosen for reasons of clarity and is generally unlimited. FIG. 6a schematically shows the zero-dimensional surrounding of an island by the inner material region 1 and the outer material region 2. FIG. 2b schematically displays the one-dimensional surrounding of a whisker by the inner material region 1 and outer material region 2.

1. Semiconductor structure consisting of at least one first material region (1) and a second material region (3), wherein the second material region (3) epitaxially surrounds the first material region (1) and forms an interface (2), the materials of the first and of the second material regions (1, 3) and/or their dimensions and/or their dopings being such that a Fermi-level-pinning (9) is observed at the epitaxial interface (4) of the second material region (3) situate opposite to the interface (2) of both material region (1, 3) and that the first material region (1) forms a quantum well for free charge carriers, the second material region (3) having several clamp-like surfaces provided epitaxially to each other.

2. (canceled)

3. The semiconductor structure according to claim 1,
characterized in that
the Fermi-Level-Pinning (9) is determined by the choice of the material and/or the dimensions and/or the doping and or the doping profile of one or both material regions (1, 3).

4. The semiconductor structure according to claim 1,
characterized in that
on the second material region (3) a further material region (5) is epitaxially provided, such that Fermi-Level-Pinning is only present at the nonepitaxial interface (6) opposite to the epitaxial interface (4) between the second and the further material region (3, 5).

5. The semiconductor structure according to claim 1,
characterized in that
the first material region (1) has a dimension a of less than 100 nanometers in x-position, especially of 0.5 to 50 nanometers.

6. The semiconductor structure according to claim 1,
characterized in that
the shortest distance of the quantum well to the nonepitaxial interface (4, 6) where the Fermi-Level-Pinning is observed does not fall below the size of the depletion length d.

7. The semiconductor structure according to claim 1,
characterized by
a material for the further material region (5) which is identical to the material of the first material region (1).

8. The semiconductor structure according to claim 1,
characterized in that
a metal is used as material for the further material region (5).

9. The semiconductor structure according to claim 1,
characterized in that
the materials of the first and of the second material regions (1, 3) show quasi lattice matching and are provided dislocation-free to each other.

10. The semiconductor structure according to claim 1,
characterized by
Al_{y}Ga_{1-y}As and AlₓGA₁₋ₓAs as materials for the first or respectively second material region (1, 3) with x>y for the formation of a step in the quantum well (band discontinuity).

11. The semiconductor structure according to claim 1, wherein there is a concentration of free charge carriers of at least 10¹⁰ cm³, particularly of at least 10¹⁶ cm⁻³ in the first material region (1).

12. The semiconductor structure according to claim 1,
characterized in that
it comprises, at least partially, metal (Schottky) electrodes (7) with gate function for the control of the charge carriers.

13. A transistor, laser, resonant tunnel diode or other hetero structure comprising a semiconductor structure according to claim 1.
